(19) United States
(12) Patent Application Publication
(10) Pub. No.: US 2011/0042762 A1
(43) Pub. Date: Feb. 24, 2011

(54) MEMS PACKAGE

(76) Inventors: Richard Ian Laming, Edinburgh (GB); Tsjerk Hans Hoekstra, Edinburgh (GB); Mark Gillson Hesketh, Edinburgh (GB)

Correspondence Address: DICKSTEIN SHAPIRO LLP, 1825 EYE STREET NW, Washington, DC, 20006-5403, US

(21) Appl. No.: 12/673,930

(22) PCT Filed: Aug. 15, 2008
(86) PCT No.: PCT/GB08/02783

§ 371 Date: Feb. 17, 2010

(30) Foreign Application Priority Data
Aug. 17, 2007 (GB) 0716187.0
Apr. 30, 2008 (GB) 0807926.1

(51) Int. Cl. H01L 29/84; H01L 21/48

(52) U.S. Cl. 257/416; 438/51; 257/E29.324; 257/E21.499

(57) ABSTRACT

The present invention provides a MEMS package, the MEMS package comprising a substrate which comprises a recess, and a MEMS device, situated in the recess.

### FIELD OF THE INVENTION

This invention relates to a MEMS device, and in particular to a MEMS package and a method of packaging a MEMS device, and in particular a MEMS capacitive microphone.

### BACKGROUND OF THE INVENTION

Consumer electronics devices are continually getting smaller and, with advances in technology, are gaining ever-increasing performance and functionality. This is clearly evident in the technology used in consumer electronic products and especially, but not exclusively, portable products such as mobile phones, laptop computers, MP3 players and personal digital assistants (PDAs). Requirements of the mobile phone industry for example, are driving the components of mobile phones to become smaller with higher functionality and reduced cost so that final products have a reduced “form factor”, i.e. thinner, shorter, etc. It is therefore desirable to integrate functions of electronic circuits together and combine them with transducer devices such as microphones and speakers.

One result of this is the emergence of micro-electrical-mechanical-systems (MEMS) based transducer devices. These may be for example, capacitive transducers for detecting and/or generating pressure/sound waves or transducers for detecting acceleration. There is a continual drive to reduce the size and cost of these devices.

Microphone devices formed using MEMS fabrication processes typically comprise a membrane with electrodes for read-out/drive deposited on the membrane and a substrate. In the case of MEMS pressure sensors and microphones, the read out is usually accomplished by measuring the capacitance between the electrodes. In the case of transducers, the device is driven by a potential difference provided across the electrodes.

FIG. 1 shows a capacitive microphone formed on a substrate 2. A first electrode 4 is mechanically connected to a membrane 6. A second electrode 8 is mechanically connected to a structurally rigid back-plate 14. A back-volume 12 is formed using an etching process from below the substrate, known as a “back-etch”. The back-volume 12 allows the membrane 6 freedom to move in response to acoustic signals.

FIG. 2 shows a package 20 for housing a MEMS device 22, for example a MEMS microphone. The MEMS device 22 is not shown in any detail here for clarity, but it can be considered to be similar to the device described with respect to FIG. 1.

The package 20 comprises a printed circuit board (PCB) 24 on which the microphone 22 is mounted. The PCB 24 is a laminate structure that comprises multiple isolation and metal layers, for example four metal layers 24a, 24b, 24c, 24d separated by respective isolation layers. Wire bonds 26, 28 are used to connect the microphone to the electric circuitry associated with the PCB 24 via electric connectors pads 30, 32. A lid 34 is used to enclose the microphone 22 within the package 20, in order to protect the microphone and circuitry from the environment. However, the lid 34 comprises a small acoustic hole 36 to allow acoustic signals to enter the package 20.

The problem with such designs in the form of a package 20 is that, as aforementioned, there is a continual drive to reduce the size, or height, of packages in order to reduce the size of the device in which they are employed. For example, mobile phones are getting smaller and thinner, and therefore there is a need for a MEMS package that has a reduced size or form factor.

### SUMMARY OF INVENTION

According to a first aspect of the present invention, there is provided a MEMS package, the MEMS package comprising a substrate which comprises a recess, and a MEMS device, situated in the recess.

According to a second aspect of the present invention, there is provided a method of manufacturing a MEMS package, the method comprising the steps of forming a cavity within a substrate and placing a MEMS device within the cavity.

### BRIEF DESCRIPTION OF THE DRAWINGS

For a better understanding of the present invention, and to show more clearly how it may be carried into effect, reference will now be made, by way of example, to the following drawings, in which:

FIG. 1 shows a MEMS capacitive microphone;

FIG. 2 shows a package for a MEMS microphone;

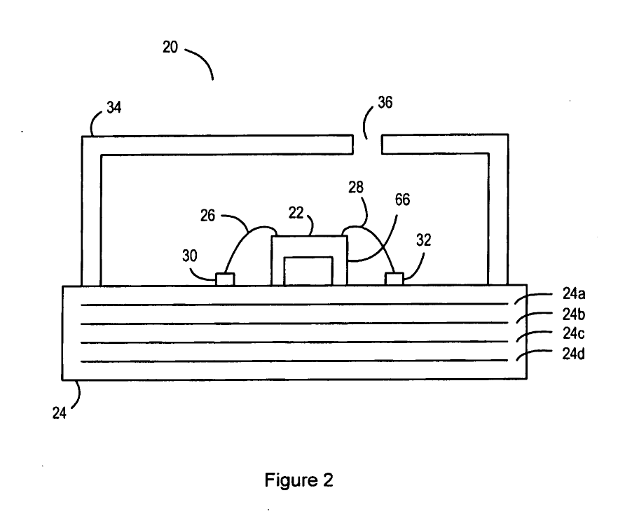

FIG. 3 shows a MEMS package according to an embodiment of the present invention; and

FIG. 4 shows one example of a substrate for use in the present invention.

### DETAILED DESCRIPTION

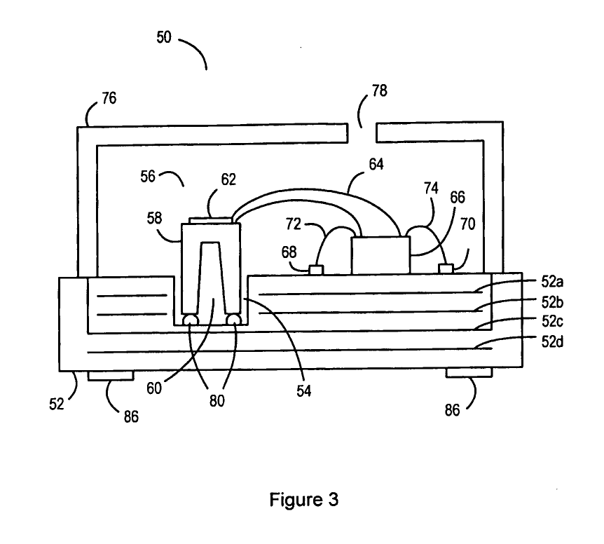

FIG. 3 shows a MEMS package 50 according to the present invention.

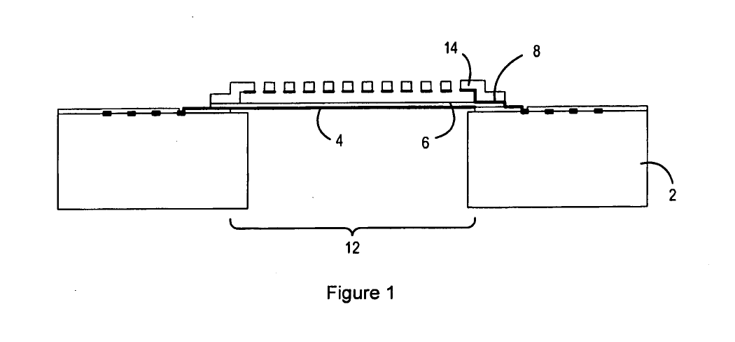

The package 50 comprises a PCB 52. According to one embodiment, the laminated PCB 52 comprises four metal layers 52a, 52b, 52c, 52d, separated by respective isolation layers. It will be appreciated, however, that the PCB 52 can comprise any number of metal layers or isolation layers. The isolation layers may comprise a dielectric material, such as fibre glass, as will be familiar to those skilled in the art. The PCB 52 may further comprise a photo resist layer (not illustrated) above the upper-most metal layer 52a. According to the present invention, the PCB 52 further comprises a cavity 54, or recess. A MEMS device 56, for example a MEMS transducer such as that described with respect to FIG. 1, is positioned within the cavity 54.

In one embodiment, the MEMS transducer 56 comprises a substrate 58 into which a back-volume 60 is formed. Across the top of the back-volume 60, a membrane 62 reacts to the changes in pressure caused by acoustic signals. The membrane 62 comprises an electrode, which is displaced relative to a fixed electrode in the rigid substrate 58 (not shown) when an acoustic signal disturbs the membrane 62. The transducer 56 may be fixed in the cavity by adhesive means 80. The adhesive means 80 may comprise solder, glue, epoxy, glass frit or any other suitable means within the knowledge of the person skilled in the art.

Wire bonds 64 connected to the respective electrodes pass signals indicative of the changes in capacitance between the electrodes to electronic circuitry. According to one embodiment, the electronic circuitry may comprise electronic circuitry 66 positioned on the substrate as shown in FIG. 3. In such an embodiment the electronic circuitry 66 is further bonded to connection pads 68, 70 by wire bonds 72, 74. The electronic circuitry 66 may be in the form of an integrated circuit located within the MEMS package. According to another embodiment, part or whole of the electronic circuitry can be embedded in the MEMS device 56. It will be appreciated that the invention is not limited to the electronic circuitry being positioned in any particular location.

A lid, or cover, 76 encloses the package and protects the components inside from environmental interference and/or damage. In one embodiment, the lid 76 comprises a conductive layer, such that the contents of the package are protected from electromagnetic interference from the environment. In an alternative embodiment, the lid 76 itself may be formed from a conductive material, such that substantially the same effect is achieved. An aperture, i.e. a hole, 78 may be provided in the lid 76. The aperture 78 may comprise an environmental barrier (not illustrated) as known to those skilled in the art, that allows acoustic signals to pass through to the MEMS device 56.

Thus, the present invention provides a reduced-height package by placing, i.e. recessing, the MEMS device 56 within a recess, or cavity 54. Although not shown in FIG. 3, it will be appreciated that the electronic circuitry 66 may also be provided in a recess or cavity, similar to that shown for the MEMS device 56. It is also noted that, as mentioned above, the MEMS device 56 may itself comprise electronic circuitry.

As shown in FIG. 3, according to one embodiment, the cavity 54 extends through two of the four metal layers 52a, 52b, and their respective isolation layers. The third metal layer 52c forms a ground plane. The lower-most metal layer 52d may be used to form contacts 86 with external circuitry (not shown). Further, according to one embodiment, the third metal layer 52c, i.e. the ground plane, is electrically connected to the conducting material in the lid 76 such that the package forms an “RF cage” or “Faraday cage”, thereby protecting the package contents from electromagnetic interference.

However, alternative configurations are possible according to the desired depth of the cavity 54 and consequently the desired height, i.e. form factor, of the package 50. For example, the PCB 52 may have greater or fewer than four metal layers, plus their respective isolation layers, and the cavity 54 may be formed through one or more of the plurality of metal and or isolation layers, depending on the reduction in package height that is required. In this instance, any one or more of the plurality of metal layers not forming part of the cavity 54 may be connected to the lid 76 to form the RF cage.

That is, in the general case, the printed circuit board may comprise N metal layers, where N is an integer. The cavity 54 may then be formed through N-M of the N metal layers, where M is a number between N and 0 that represents the number of metal layers through which the cavity 54 is not formed.

For example, depending on the form factor (i.e. the height of package) that is required, it may be sufficient for the cavity 54 to be formed through just the solder resist layer. That is, the photo resist layer may be etched away by either a dry- or a wet-etch, as will be familiar to those skilled in the art. This will typically provide a reduction in form factor of 30 to 40 μm. If further reductions in form factor are required, the first metal layer 52a may be etched to extend the cavity 54 further, providing a further reduction of about 10 to 20 μm. If yet further reductions in form factor are required, the first isolation layer beneath the first metal layer 52a may be mechanically removed such as by milling. This process may be repeated until the form factor has been reduced sufficiently according to the requirements of the package designer.

Similar considerations to the above also apply if the electronic circuitry 66 is to be placed in a recess or cavity.

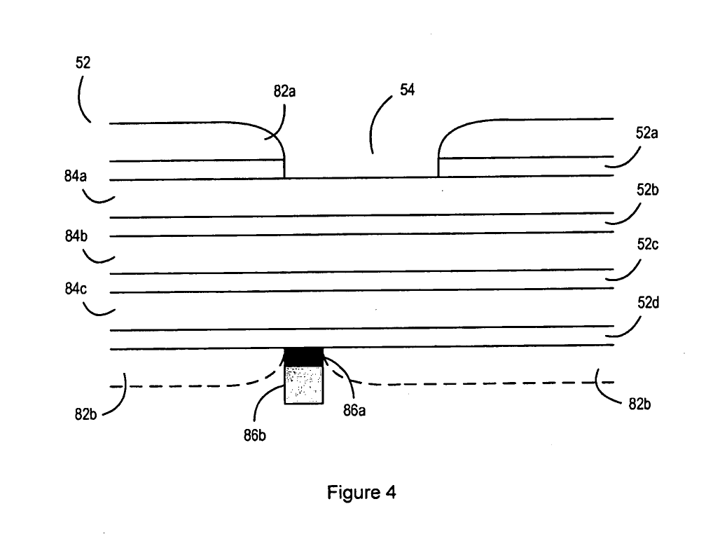

FIG. 4 is a schematic drawing showing the PCB 52 in greater detail.

As aforementioned, in one embodiment, the PCB 52 comprises four metal layers 52a, 52b, 52c, 52d. The thickness of each metal layer is approximately 10 to 20 μm.

Separating the four metal layers are three dielectric isolation layers 84a, 84b, 84c, with each isolation layer being approximately 40 to 80 μm thick. The dielectric isolation layers 84a, 84b, 84c may comprise fibre glass, or any other material familiar to those skilled in the art. Above the upper-most metal layer 52a is a photo resist layer 82a, which is approximately 30 to 40 μm thick. Alternatively, the photo resist layer 82a may be a solder resist layer. Optionally, there may be a second photo or solder resist layer 82b on the underside of the PCB 52, i.e. below the lower-most metal layer 52d.

In the embodiment shown in FIG. 4, the lower-most metal layer 52d is used to form electrical contacts with external circuitry. In the case where the PCB 52 does not comprise a lower photo/solder resist layer, all that is required is a relatively small contact 86a. In the case where the PCB 52 does comprise a lower photo/solder resist layer 82b, a larger contact is required in order to extend the contact beyond the photo/solder resist layer 82b. Thus, in this instance, the contact would comprise both portions 86a and 86b shown in FIG. 4.

In the embodiment shown, the cavity 54 is formed through the upper photo resist layer 82a and the uppermost metal layer 52a.

As discussed above, the depth of the recess can be increased by milling through the isolation layer 84a, and increased further by etching through the metal layer 52b, and so forth.

In one embodiment, the task of processing and routing the signals from the MEMS transducer 56 is carried out by the electronic circuitry 66 housed within the package 50. However, in alternative embodiments the electronic circuitry 66 may be located outside the package 50, i.e. on a separate chip or integrated circuit. In such an embodiment the output of the MEMS transducer 56 is connected directly to a contact 86. In yet further alternative embodiments the electronic circuitry necessary for processing the signals from the MEMS transducer 56 may be incorporated on the MEMS transducer 56 itself, either positioned above, adjacent to, or below the back-plate. The circuitry may be positioned on the floor of the cavity 54, with the MEMS transducer 56 positioned above. A further alternative involves having part of the circuitry on the MEMS device, e.g. a Low Noise Amplifier, with the remaining circuitry either located within the package 50 or on a separate chip or integrated circuit.

The cavity 54 may be formed by a number of different processes. For example, as aforementioned, the PCB 52 comprises several layers of different materials. In order to remove part of the upper-most layer, the photo resist, or one of the metal layers 52a, 52b, 52c, 52d, the metal may be either wet- or dry-etched as will be familiar to those skilled in the art. In order to remove part of the isolation layers to create the cavity 54, the isolation layers may be milled, as will be familiar to those skilled in the art.

In one embodiment, the PCB 52 may be designed with a redundant area specifically included in each metal layer that is disturbed by the cavity. In this embodiment, the cavity 54 is formed within the redundant area of each metal layer.

The above description has focused on the use of a printed circuit board as the substrate in which the cavity 54 is formed. However, it will be apparent to those skilled in the art that alternative materials may be used that still fall within the scope of the invention. For example, the substrate may comprise a ceramic material in which the cavity is formed.

Further, the above description has focused on a package for a MEMS transducer, or a MEMS microphone. However, any MEMS device is contemplated to be included within the cavity of the package of the present invention.

It is noted that the invention may be used in a number of applications. These include, but are not limited to, consumer applications, medical applications, industrial applications and automotive applications. For example, typical consumer applications include laptops, mobile phones, PDAs and personal computers. Typical medical applications include hearing aids. Typical industrial applications include active noise cancellation. Typical automotive applications include hands-free sets, acoustic crash sensors and active noise cancellation.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1. A MEMS package, comprising:
a substrate, comprising a recess; and
a MEMS device, situated in the recess.

2. A MEMS package as claimed in claim 1, wherein the MEMS device is a transducer.

3. A MEMS package as claimed in claim 1, wherein the substrate comprises a plurality of layers, and wherein the recess is formed through one or more of the plurality of layers.

4. A MEMS package as claimed in claim 1, wherein the substrate comprises a ceramic substrate.

5. A MEMS package as claimed in claim 1, wherein the substrate comprises a printed circuit board.

6. A MEMS package as claimed in claim 3, wherein the plurality of layers comprises a photo resist or solder resist layer.

7. A MEMS package as claimed in claim 6, wherein the recess is formed through the photo resist or solder resist layer.

8. A MEMS package as claimed in claim 3, wherein the plurality of layers further comprises N metal layers, and wherein the recess is formed through N-M of the N metal layers.

9. A MEMS package as claimed in claim 8, wherein each metal layer of the N-M metal layers comprises a redundant area, and wherein the recess is formed within the redundant area of each of the N-M metal layers.

10. A MEMS package as claimed in claim 8, wherein M=2.

11. A MEMS package as claimed in claim 5, wherein the plurality of layers further comprises a plurality of dielectric isolation layers.

12. A MEMS package as claimed in claim 1, further comprising a cover enclosing the MEMS device and the recess.

13. A MEMS package as claimed in claim 12, wherein the cover is a conductor.

14. A MEMS package as claimed in claim 12, wherein the cover comprises a conducting layer.

15. A MEMS package as claimed in claim 13, wherein the substrate comprises a printed circuit board comprising a plurality of metal layers, wherein the recess is formed through one or more of the plurality of metal layers, wherein at least one of the plurality of metal layers through which the recess is not formed is electrically connected to the cover.

16. A MEMS package as claimed in claim 12, wherein the cover comprises an opening for allowing acoustic signals to enter the package.

17. A MEMS package as claimed in claim 16, wherein the opening comprises an environmental barrier.

18. A MEMS package as claimed in claim 1, wherein the MEMS device comprises electronic circuitry.

19. A MEMS package as claimed in claim 1, further comprising an integrated circuit, wherein the integrated circuit is situated in a recess.

20. A method of manufacturing a MEMS package, the method comprising:
forming a cavity within a substrate; and
placing a MEMS device within the cavity.

21. A method as claimed in claim 20, wherein the MEMS device is a transducer.

22. A method as claimed in claim 20, wherein the substrate comprises a plurality of layers, and wherein the forming step comprises: forming the cavity through one or more of the plurality of layers.

23. A method as claimed in claim 20, wherein the substrate comprises a ceramic substrate.

24. A method as claimed in claim 20, wherein the substrate comprises a printed circuit board.

25. A method as claimed in claim 22, wherein the plurality of layers comprises a solder resist or photo resist layer, and wherein the forming step comprises etching the solder resist or photo resist layer to create the cavity.

26. A method as claimed in claim 22, wherein the plurality of layers further comprises N metal layers, and wherein the forming step further comprises the substep of etching N-M metal layers fo the N metal layers to create the cavity.

27. A method as claimed in claim 26, wherein each metal layer of the N-M metal layers comprises a redundant area, and wherein the cavity is formed within the redundant area of each of the N-M metal layers.

28. A method as claimed in claim 26, wherein M=2.

29. A method as claimed in claim 22, wherein the plurality of layers further comprises a plurality of dielectric isolation layers, and wherein the forming step further comprises milling one or more of the plurality of dielectric isolation layers to create the cavity.

30. A method as claimed in claim 20, further comprising:
creating a cover to enclose the MEMS device and the cavity.

31. A method as claimed in claim 30, wherein the substrate comprises a printed circuit board comprising N metal layers, wherein the cavity is formed through N-M of the N metal layers, and wherein the cover comprises a conducting material, the method further comprising:
electrically connecting to the conducting material of the cover at least one of the M metal layers through which the cavity is not formed.

32. A method as claimed in claim 30, further comprising the step of providing an opening in the cover for allowing acoustic signals to enter the package.

33. A method as claimed in claim 32, further comprising the step of providing an environmental barrier for the opening.

34. A method as claimed in claim 20, further comprising the step of providing electronic circuitry on the MEMS device.

35. A method as claimed in claim 20, further comprising the step of providing an integrated circuit within the MEMS package, wherein the integrated circuit is situated in a recess.

36. (canceled)
